(19) United States
(12) Patent Application Publication
(10) Pub. No.: US 2019/0024226 A1
(43) Pub. Date: Jan. 24, 2019

(54) METHOD OF MANUFACTURING A PIN FOR A MOLD FOR A DIE CASTING PROCESS

(71) Applicant: GM GLOBAL TECHNOLOGY OPERATIONS LLC, Detroit, MI (US)

(72) Inventors: Bin Hu, Shanghai (CN); Pan Wang, Shanghai (CN); Yiwu Xu, Shanghai (CN)

(73) Assignee: GM GLOBAL TECHNOLOGY OPERATIONS LLC, Detroit, MI (US)

(21) Appl. No.: 16/070,699

(22) PCT Filed: Jan. 22, 2016
(86) PCT No.: PCT/CN2016/071753

§ 371 Date: Jul. 17, 2018

(51) Int. Cl. C23C 8/24; C23C 14/06; B22D 17/22; C21D 9/00

(52) U.S. Cl. CPC C23C 8/24; C23C 14/06; C21D 2221/10; C21D 9/0068; B22D 17/2236

(57) ABSTRACT

A method of manufacturing a pin (46) for a o mold (28) includes forming the pin (46) to include a substantially uniform initial hardness throughout the entire structure of the formed pin (46). The formed pin (46) is then processed with a hardening process, such that the processed pin(46) exhibits a hardness defining a hardness gradient that gradually increases from the initial hardness at a central interior region (56) of the pin (46) to an increased surface hardness at an exterior surface (60) of the pin (46). After processing the pin (46) with the hardening process, a coating (64) maybe deposited onto the exterior surface (60) of the pin (46) with a physical vapor deposition process. The coating (64) exhibits a hardness that is greater than the hardness of the increased surface hardness of the exterior surface (60) of the pin (46). The pin (46) may include, for example, a core pin, a squeeze pin, or an ejector pin.

### TECHNICAL FIELD

The disclosure generally relates to a method of manufacturing a pin for a mold for a die casting process.

### BACKGROUND

A die casting mold mainly includes a die set having a first die half and a second die half. The first die half and the second die half oppose each other, and cooperate together to form a mold that defines a casting cavity between the first die half and the second die half. Molten metal is introduced into the casting cavity, and once solidified, forms the cast part. The mold may include one or more different mold pins. The different types of mold pins may include, for example, a core pin, a squeeze pin, or an ejector pin. For example, the mold may include an ejector pin for ejecting a cast article from the casting cavity. Another embodiment of a mold pin may include a core pin for forming a void in the cast part, e.g., a bore, hole, aperture, etc. The core pin is attached to one of the die halves, and extends into the casting cavity. The molten metal flows around the core pin, and when the cast part is removed from the mold by the ejector pins when the die set is opened, the core pin leaves the desired void in the cast part. Furthermore, the mold may include a squeeze pin for local compression in order to eliminate porosity in castings having a complex shape and/or thick wall regions. The mold may be equipped with several different types of the mold pins, including but not limited to the core pins, the ejector pins and/or the squeeze pins.

The pins used in the mold typically include a life cycle that is significantly less than that of the mold. When the pins break or otherwise fail, it is replaced in the mold. Replacing the pins requires significant down time for the mold, and requires that the mold be re-heated. Re-heating the mold includes running several shots of casting material through the mold, which then becomes scrap material.

### SUMMARY

A method of manufacturing a pin for a mold for a die casting process is provided. The method includes forming the pin from a metal material to define a desired shape. The pin is formed to include a substantially uniform initial hardness throughout the entire structure of the formed pin. The formed pin is then processed with a hardening process, such that the processed pin exhibits a hardness that gradually increases from the initial hardness at a central interior region of the pin to an increased surface hardness at an exterior surface of the pin.

A method of manufacturing a mold for a die casting process is also provided. The method includes forming a pin from a metal material to define a desired shape. As formed, the pin includes a substantially uniform initial hardness throughout the entire structure of the formed pin. The formed pin is then processed with a hardening process, such that the processed pin exhibits a hardness defining a hardness gradient that gradually increases from the initial hardness at a central interior region of the pin to an increased surface hardness at an exterior surface of the pin. After processing the pin with the hardening process, a ceramic coating is deposited onto the exterior surface of the pin with a physical vapor deposition process. The ceramic coating exhibits a hardness that is greater than the hardness of the increased surface hardness of the exterior surface of the pin. The pin is then attached to a first die half, which cooperates with a second die halve to form the mold defining a casting cavity for the die casting process.

Accordingly, the pin is manufactured in a manner that increases the hardness of the pin, thereby increasing its durability and life cycle, without making it excessively brittle.

The above features and advantages and other features and advantages of the present teachings are readily apparent from the following detailed description of the best modes for carrying out the teachings when taken in connection with the accompanying drawings.

### BRIEF DESCRIPTION OF THE DRAWINGS

FIG. 1 is a schematic cross sectional view of a die casting process, showing a mold having a first die half and a second die half.

FIG. 2 is a schematic cross sectional view of a pin after the pin has been initially formed, showing a uniform hardness throughout the entire pin.

FIG. 3 is a schematic cross sectional view of the pin after the pin has been processed with a hardening process, showing a hardness gradient between a central region of the pin and an exterior surface of the pin.

FIG. 4 is a schematic cross sectional view of the pin after a coating has been applied to the processed pin.

FIG. 5 is an enlarged schematic cross sectional view of the first die half showing the pin.

### DETAILED DESCRIPTION

Those having ordinary skill in the art will recognize that terms such as “above,” “below,” “upward,” “downward,” “top,” “bottom,” etc., are used descriptively for the figures, and do not represent limitations on the scope of the disclosure, as defined by the appended claims. Furthermore, the teachings may be described herein in terms of functional and/or logical block components and/or various processing steps. It should be realized that such block components may be comprised of any number of hardware, software, and/or firmware components configured to perform the specified functions.

Referring to the Figures, wherein like numerals indicate like parts throughout the several views, a die casting system is schematically shown at 20. The die casting system 20 is used to cast an article 30. While the die casting system 20 may be used with any suitable material, the die casting system 20 is particularly suited for casting the article 30 from a metal, such as steel, aluminum or magnesium.

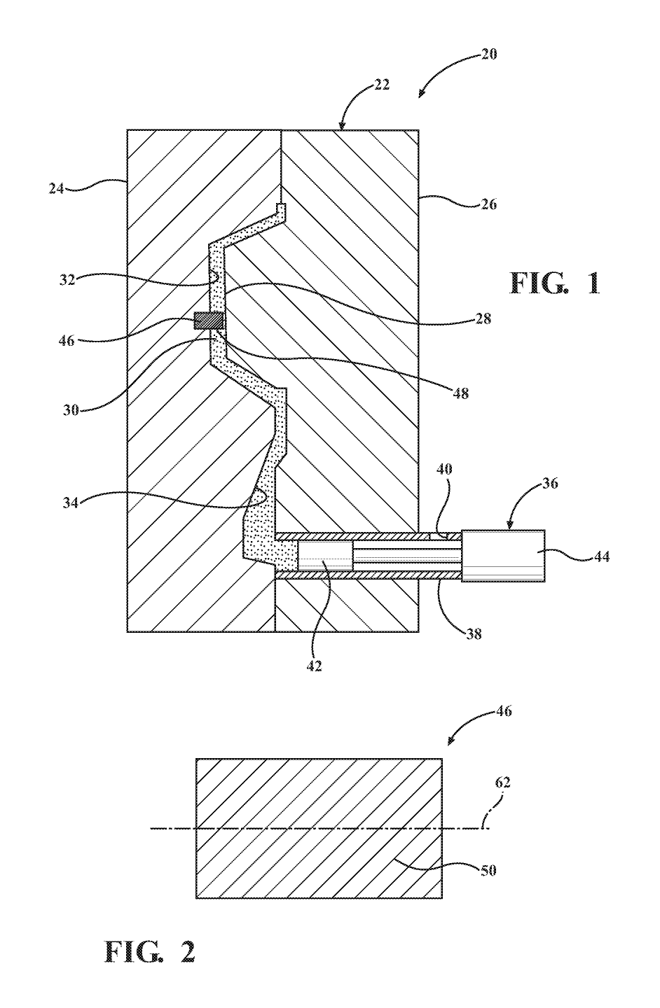

Referring to FIG. 1, the die casting system 20 includes a die set 22. The die set 22 includes a first die half 24 and a second die half 26 opposing each other to form a mold 28. One of the first die half 24 and the second die half 26 may be referred to as a moving die, and the other may be referred to as a stationary die. As shown, the first die half 24 is the moving die, and the second die half 26 is the stationary die. However, it should be appreciated that the relative positions of each may be reversed, with the first die half 24 being the stationary die, and the second die half 26 being the moving die. The moving die moves into and out of engagement with the stationary die during the casting process to release a formed article 30.

The first die half 24 and the second die half 26 cooperate together to define a casting cavity 32 and a gate cavity 34 therebetween. The casting cavity 32 forms the shape of the article 30. The gate cavity 34 forms a volume that is used to feed a molten material into the casting cavity 32. The gate cavity 34 may be formed in any suitable manner to properly feed the molten material into the casting cavity 32. Accordingly, the shape and orientation of both the casting cavity 32 and the gate cavity 34 will depend upon the particular shape of the article 30 to be cast.

The die casting system 20 further includes a melt injection system 36. The melt injection system 36 is disposed in fluid communication with the gate cavity 34. The melt injection system 36 is operable to introduce the molten material into the gate cavity 34, and thereby into the casting cavity 32. The melt injection system 36 may be configured in any suitable manner capable of introducing the molten material into the gate cavity 34. For example, the melt injection system 36 may include a shot sleeve 38 disposed in fluid communication with the gate cavity 34. The shot sleeve 38 defines a staging volume, and is operable to receive a quantity of molten material into the staging volume through an opening 40 in the shot sleeve 38. A plunger 42 is moveable through the staging volume of the shot sleeve 38. The plunger 42 is operable to force the molten material in the staging volume of the shot sleeve 38, into the gate cavity 34, and then into the casting cavity 32. The plunger 42 may be connected to and powered by an actuator 44, such as but not limited to a hydraulic ram or other similar linear actuator 44.

One or both of the first die half 24 and/or the second die half 26 may include one or more pins 46. The pins 46 may include, but are not limited to one of a core pin, a squeeze pin, or an ejector pin. As shown, the first die half 24 includes the pin 46. While only one pin 46 is shown, it should be appreciated that the die set 22 may include multiple pins 46. Furthermore, while the exemplary embodiment shown in the Figures includes the pin 46 shown attached to the first die half 24, it should be appreciated that the pin 46 may alternatively be attached to the second die half 26, or that the die set 22 may include multiple pins 46, with some of the pins 46 attached to the first die half 24, and the remainder of the pins 46 attached to the second die half 26. The pin 46 is attached to and supported by the first die half 24, and extends into the casting cavity 32. As is known in the art, the molten material injected into the casting cavity 32 flows around the pin 46, such that the pin 46 forms a void 48 in the cast article 30.

A method of manufacturing the mold 28 for the die casting process, and specifically a method of manufacturing the pin 46 for the mold 28 of the die casting process, is described below. Referring to FIG. 2, the method includes forming the pin 46 from a metal material to define a desired shape. Preferably, the pin 46 is formed from tooling steel, or a high alloy steel. However, it should be appreciated that the pin 46 may be formed from some other material suitable for use inside the mold 28. The shape of the pin 46 may vary, and depends upon the desired shape of the void 48 that must be formed in the cast article 30. For example, if the pin 46 is to form a cylindrical bore in the cast article 30, then the pin 46 may be formed to include a corresponding, elongated cylindrical shape. However, it should be appreciated that the shape of the pin 46 may differ from the exemplary cylindrical shape described herein and shown in the Figures, and may include some other shape.

The pin 46 is formed to include a substantially uniform initial hardness throughout the entire structure of the formed pin 46. In other words, after the initial formation of the pin 46, the hardness of the pin 46 is substantially the same throughout the entire length and cross section of the pin 46. The uniform initial hardness of the pin 46 is generally indicated by the consistent hatching throughout the cross section shown in FIG. 2. The initial hardness of the pin 46 may vary depending upon the specific material used to form the pin 46. For example, in an exemplary embodiment, the pin 46 may include an initial hardness between the range of HRC20 and HRC50 as defined by the Rockwell hardness test.

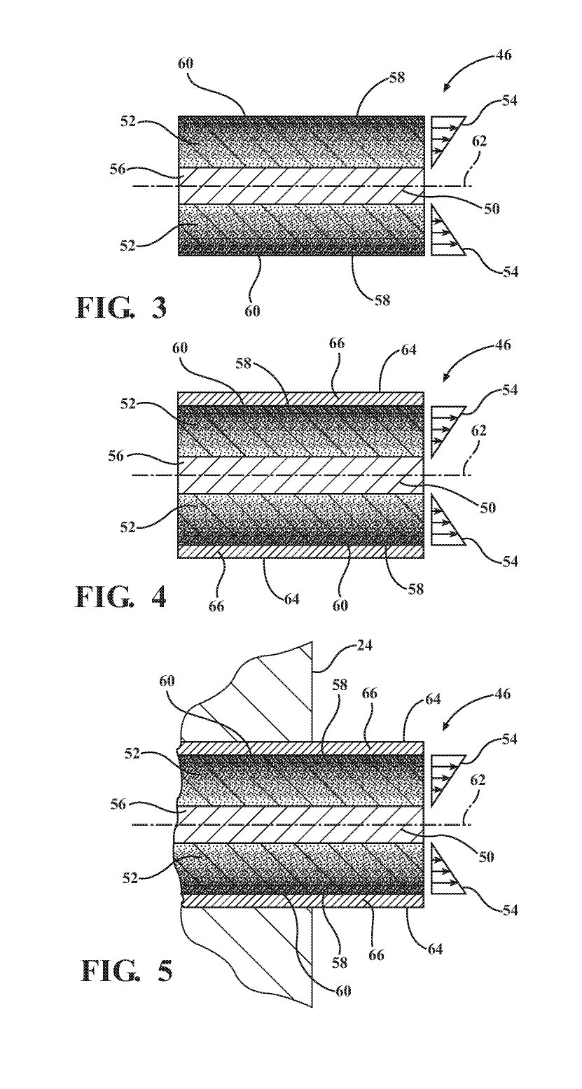

In order to increase the durability of the pin 46, the formed pin 46 is processed with a hardening process. Referring to FIG. 3, the processed pin 46 exhibits a hardness defining a hardness gradient that gradually increases from the initial hardness at a central interior region 56 of the pin 46, to an increased surface hardness 58 at an exterior surface 60 of the pin 46. The initial hardness of the central region 56 is generally indicated by the uniform hatching 50, whereas the increased hardness of the pin 46 that defines the hardness gradient is generally indicated by the variable density hatching 52. Accordingly, the hardness gradient is an increase in the hardness of the pin 46 with an increase in the distance from the central region 56 of the pin 46. The farther from the central region 56 of the pin 46, the higher the hardness value. A gradient line 54 represents the hardness gradient, and represents an increase in the hardness of the pin 46 from the initial hardness to the increased surface hardness 58. The hardness gradient structure of the pin 46 dramatically improves the stiffness and fatigue life of the pin 46 during the die casting process, thereby increasing the life cycle of the pin 46.

The central region 56 may be defined as a central longitudinal axis 62 of the pin 46, such that the hardness gradient begins at the central longitudinal axis 62 and increases with an increase in radial distance from the central longitudinal axis 62.

Alternatively, the central region 56 may define a volume or portion of the pin 46 that is centrally located along the central longitudinal axis 62 of the pin 46. In other words, the central region 56 may include a volume defined by a length of the pin 46 and a radial distance measured from the central longitudinal axis 62 of the pin 46. If the central region 56 defines a volume, such as shown in the Figures, it should be appreciated that the hardness of the pin 46 through the entirety of the central region 56 is not significantly affected by the hardening process, and the hardness of the pin 46 in the central region 56 remains substantially constant at the initial hardness of the pin 46. One exemplary embodiment of the pin 46 includes the central region 56 having a maximum volume of between 0% and 30% of a total volume of the pin 46.

It should be appreciated that the hardness of the portion of the pin 46 that is not part of the central region 56 is increased by the hardening process, in accordance with the hardness gradient, so that the exterior surface 60 of the pin 46 exhibits a hardness that is equal to the increased surface hardness 58. In one exemplary embodiment, the increased surface hardness 58 at the exterior surface 60 of the pin 46 is between the range of HRC40 and HRC55 as defined by the Rockwell hardness test.

The hardening process used to process the pin 46 may include any process that is capable of increasing the hardness and creating the hardness gradient in the pin 46. For example, the hardening process may include, but is not limited, to a Nitriding heat treatment process, or a severe deformation process.

As is known in the art, nitriding is a heat treatment process that diffuses nitrogen into the surface of a metal to create a case-hardened surface. The nitrogen may be diffused into the surface of the metal via a gas nitriding process, a salt bath nitriding process, or a plasma nitriding process. The gas nitriding process is well suited for use in hardening the pin 46, and is briefly described herein. The gas nitriding process includes heating the work piece, and bringing ammonia (NH₃) gas into contact with the work piece. When the ammonia comes into contact with the heated work piece, the ammonia disassociates into nitrogen and hydrogen. The nitrogen then diffuses onto the surface of the material creating a nitride layer. While the gas nitriding process has been briefly described herein, it should be used that other nitriding processes may be used to harden the pin 46 and form the hardness gradient in the pin 46.

The severe deformation process for hardening the pin 46 and forming the hardness gradient in the pin 46 may include any process that applies high pressure to the pin 46 to compress the particles of the pin 46 into the hardness gradient. For example, the severe deformation process may include, but is not limited to, a high energy blasting process or a grinding process. The high energy blasting process may include blasting the pin 46 with steel balls at high velocity, to compress the particles of the pin 46. The grinding process may include a surface grinding process that is applied under pressure.

Referring to FIG. 4, once the pin 46 has been processed to increase the hardness of the pin 46 and form the hardness gradient in the pin 46, a coating 64 may be deposited onto the exterior surface 60 of the pin 46. The coating 64 may be applied in any suitable manner. For example, the coating 64 may be applied using a physical vapor deposition process. The coating 64 exhibits a hardness that is greater than the hardness of the increased surface hardness 58 of the exterior surface 60 of the pin 46. The hardness of the coating 64 is generally indicated by hatching 66. Preferably, the coating 64 includes a ceramic coating 64. However, it should be appreciated that the coating 64 may include some other material not specifically disclosed herein, that exhibits a hardness that is greater than the increased surface hardness of the pin 46. In an exemplary embodiment, the coating 64 exhibits a hardness greater than HRC80 as defined by the Rockwell hardness test.

Physical vapor deposition processes include a variety of vacuum deposition methods used to deposit thin films of condensation of a vaporized form of the coating 64 material onto the work piece to form the coating 64. The physical vapor deposition processes are known to those skilled in the art, and are therefore not described in detail herein.

If the pin 46 is to be processed using the gas nitriding heat treatment process, the pin 46 must be placed in a chamber. The chamber is operable to seal the pin 46 so that the pin 46 may be subjected to the ammonia gas. If the pin 46 is to include the coating 64, which is applied using the physical vapor deposition process, then it is contemplated that the physical vapor deposition process may be performed with the pin 46 in the same chamber used to perform the gas nitriding heat treatment process, without removing the pin 46 from the chamber. As such, the chamber may be used to perform both the gas nitriding heat treatment process and the physical vapor deposition process. To do so, the formed pin 46 is placed in the chamber and processed to harden the pin 46 and form the hardness gradient in the pin 46 using the gas nitriding heat treatment process, and then the coating 64 is applied to the pin 46 using the physical vapor deposition process, prior to removing the pin 46 from the chamber.

Referring to FIG. 5, once the pin 46 has been processed to increase the hardness of the pin 46 and form the hardness gradient, and the coating 64 has been applied (if desired), then the pin 46 is attached to a respective die halve, i.e., either the first die half 24 or the second die half 26. As noted above, the pin 46 is attached to one of the die halves, and extends into the casting cavity 32 of the mold 28 so that the molten material may flow around the pin 46, thereby forming a void 48 in the cast article 30 once solidified. The pin 46 may be attached to the first die half 24 in any suitable manner. Those skilled in the art are familiar with the processes used to attach a pin 46 to a die half. Accordingly, the specific process of attaching the pin 46 to the first die half 24 is not described in detail herein.

The detailed description and the drawings or figures are supportive and descriptive of the disclosure, but the scope of the disclosure is defined solely by the claims. While some of the best modes and other embodiments for carrying out the claimed teachings have been described in detail, various alternative designs and embodiments exist for practicing the disclosure defined in the appended claims.

1. A method of manufacturing a pin for a mold for a die casting process, the method comprising:
forming the pin from a metal material to define a desired shape, such that the pin includes a substantially uniform initial hardness throughout the entire structure of the formed pin; and
processing the formed pin with a hardening process such that the processed pin exhibits a hardness that gradually increases from the initial hardness at a central interior region of the pin to an increased surface hardness at an exterior surface of the pin.

2. The method set forth in claim 1 further comprising depositing a coating onto the exterior surface of the pin with a physical vapor deposition process, wherein the coating exhibits a hardness that is greater than the hardness of the increased surface hardness of the exterior surface of the pin.

3. The method set forth in claim 2 wherein the coating is a ceramic coating.

4. The method set forth in claim 2 wherein the coating exhibits a hardness greater than HRC80 as defined by the Rockwell hardness test.

5. The method set forth in claim 1 wherein the initial hardness of the pin is between the range of HRC20 and HRC50 as defined by the Rockwell hardness test.

6. The method set forth in claim 5 wherein the increased surface hardness at the exterior surface of the pin is between the range of HRC40 and HRC55 as defined by the Rockwell hardness test.

7. The method set forth in claim 1 wherein the central region of the pin includes a maximum volume of between 0% and 30% of a total volume of the pin.

8. The method set forth in claim 1 wherein processing the formed pin with the hardening process is further defined as processing the formed pin with a Nitriding heat treatment process.

9. The method set forth in claim 8 further comprising depositing a coating onto the exterior surface of the pin with a physical vapor deposition process, after the Nitriding heat treatment process, wherein the coating exhibits a hardness that is greater than the hardness of the increased surface hardness of the exterior surface of the pin.

10. The method set forth in claim 9 further comprising placing the formed pin into a chamber prior to processing the formed pin with the Nitriding heat treatment process.

11. The method set forth in claim 10 wherein the steps of processing the formed pin with the Nitriding heat treatment process and depositing the coating onto the exterior surface of the pin after the Nitriding heat treatment process are both performed with the pin in the chamber.

12. The method set forth in claim 1 wherein processing the formed pin with the hardening process is further defined as processing the formed pin with a severe deformation process.

13. The method set forth in claim 12 wherein the severe deformation process includes one of a high energy blasting process or a grinding process.

14. The method set forth in claim 12 further comprising depositing a coating onto the exterior surface of the pin with a physical vapor deposition process, after the severe deformation process, wherein the coating exhibits a hardness that is greater than the hardness of the increased surface hardness of the exterior surface of the pin.

15. A method of manufacturing a mold for a die casting process, the method comprising:
forming a pin from a metal material to define a desired shape, such that the pin includes a substantially uniform initial hardness throughout the entire structure of the formed pin;
processing the formed pin with a hardening process such that the processed pin exhibits a hardness defining a hardness gradient that gradually increases from the initial hardness at a central interior region of the pin to an increased surface hardness at an exterior surface of the pin;
depositing a ceramic coating onto the exterior surface of the pin with a physical vapor deposition process, after processing the pin with the hardening process, wherein the ceramic coating exhibits a hardness that is greater than the hardness of the increased surface hardness of the exterior surface of the pin; and
attaching the pin to a first die half, which cooperates with a second die half to form the mold defining a casting cavity for the die casting process.

16. The method set forth in claim 15 wherein:
the initial hardness of the central region of the pin is between the range of HRC20 and HRC50 as defined by the Rockwell hardness test;
the increased surface hardness at the exterior surface of the pin is between the range of HRC40 and HRC55 as defined by the Rockwell hardness test; and
the ceramic coating exhibits a hardness greater than HRC80 as defined by the Rockwell hardness test.

17. The method set forth in claim 16 wherein the central region of the pin includes a maximum volume of between 0% and 30% of a total volume of the pin.

18. The method set forth in claim 17 wherein processing the formed pin with the hardening process is further defined as processing the formed pin with a Nitriding heat treatment process.

19. The method set forth in claim 18 wherein the steps of processing the formed pin with the Nitriding heat treatment process and depositing the coating onto the exterior surface of the pin after the Nitriding heat treatment process are both performed consecutively with the pin disposed in a single chamber.

20. The method set forth in claim 17 wherein processing the formed pin with the hardening process is further defined as processing the formed pin with a severe deformation process, wherein the severe deformation process includes one of a high energy blasting process or a grinding process.
